(19) United States
(12) Patent Application Publication
(10) Pub. No.: US 2025/0293103 A1
(43) Pub. Date: Sep. 18, 2025

(54) Cavity Formation Using Depth Routing, Component Carrier and Component Carrier Assembly

(71) Applicant: AT&S Austria Technologie & Systemtechnik Aktiengesellschaft, Leoben (AT)

(72) Inventors: Nick XIN, Shanghai (CN); Mikael Andreas TUOMINEN, Pernio (FI); Seok Kim TAY, Singapore (SG); Mengjingzi ZONG, Shanghai (CN)

(21) Appl. No.: 18/860,322

(22) PCT Filed: Apr. 24, 2023
(86) PCT No.: PCT/EP2023/060657

§ 371 Date: Oct. 25, 2024

(30) Foreign Application Priority Data
Apr. 25, 2022 (CN) 202210442013.9

(51) Int. Cl. H01L 23/053; H01L 21/48

(52) U.S. Cl. CPC H01L 23/053; H01L 21/4846

(57) ABSTRACT

A component carrier, includes i) a stack having at least one electrically insulating layer structure and at least one electrically conductive layer structure; ii) a cavity formed in the stack; iii) an electrically insulating material layer arranged in the stack, at least partially defining the bottom of the cavity; and iv) a metal layer arranged in the stack below the electrically insulating material layer where the bottom of the cavity includes a bottom surface encircled by the sidewalls of the cavity, and a peripheral recess is formed on the bottom of the cavity.

### CROSS REFERENCE TO RELATED APPLICATIONS

This application is a national stage application, filed under 35 U.S.C. § 371, of International Patent Application No. PCT/EP2023/060657, filed on Apr. 24, 2023, claiming priority of patent application Ser. No. 202210442013.9 filed on Apr. 25, 2022, in China, these patent applications being incorporated by reference herein in their entirety.

### TECHNICAL FIELD

The disclosure relates to a component carrier with a layer stack and a cavity in the layer stack, which cavity has been formed by depth routing. Further, the disclosure relates to a component carrier assembly that comprises the component carrier and a further component carrier. Furthermore, the disclosure relates to a method of manufacturing the component carrier. Additionally, there is described a specific use of depth routing.

Accordingly, the disclosure may relate to the technical field of component carriers such as printed circuit boards or IC substrates and their manufacture.

### TECHNOLOGICAL BACKGROUND

In the context of growing product functionalities of component carriers equipped with one or more electronic components and increasing miniaturization of such electronic components as well as a rising number of electronic components to be mounted on the component carriers such as printed circuit boards, increasingly more powerful array-like components or packages having several electronic components are being employed, which have a plurality of contacts or connections, with ever smaller spacing between these contacts. Removal of heat generated by such electronic components and the component carrier itself during operation becomes an increasing issue. Also, an efficient protection against electromagnetic interference (EMI) becomes an increasing issue. At the same time, component carriers shall be mechanically robust and electrically and magnetically reliable so as to be operable even under harsh conditions.

Especially providing an accurate cavity in a component carrier may be considered a challenge. Conventionally, cavities are formed in circuit boards by mechanical or laser drilling, which may be a challenge, when the component carrier comprises a certain number of layers in the stack. Here, an accurate drilling depth, as well as the shape of sidewalls after drilling, may become an issue.

However, there may be a demand for highly accurate cavities in thin component carriers that, nevertheless, comprise a high number of layers in the stack. Such cavities may be needed, for example, to efficiently accommodate an electronic component in a component carrier assembly.

As can be seen in FIG. 4, such conventional assemblies 300 of stacked component carriers 310, 340 depend on additional interposer structures 330 to embed a component 320, thereby generating a potentially unacceptable high thickness.

### SUMMARY OF THE DISCLOSURE

There may be a need to form a cavity in a component carrier layer stack in an accurate and reliable manner.

A component carrier, a component carrier assembly, a method of manufacturing, and a method of using depth routing are provided.

According to an aspect of the disclosure, there is described a component carrier comprising: i) a stack comprising at least one electrically insulating layer structure and at least one electrically conductive layer structure; ii) a cavity (recess) formed in the stack; iii) an electrically insulating material layer (structure) (in particular comprising an elevated central part and a groove-shaped surrounding part) arranged in the stack, in particular at least partially defining the bottom of the cavity; and iv) a metal layer (e.g., a continuous or discontinuous copper layer) arranged in the stack (in particular directly) below the electrically insulating material layer where the bottom of the cavity comprises a bottom surface encircled by the sidewalls (the sidewalls and the bottom may define the cavity) of the cavity, and a peripheral recess (e.g., comprising or consisting of a hole and a groove) is formed on the bottom of the cavity.

According to a further aspect of the disclosure, there is described a component carrier assembly, comprising: i) a further component carrier (e.g., a main board) as a base structure; ii) an electronic component (e.g., an IC) mounted on the further component carrier; and iii) a component carrier (e.g., a board with an RF functionality) as described above as a cover structure. Hereby, the component carrier is arranged on the further component carrier, so that the electronic component is located at least partially in the cavity.

According to a further aspect of the disclosure, there is described a method of manufacturing a component carrier (e.g., as described above), the method comprising: i) providing a stack comprising at least one electrically insulating layer structure and at least one electrically conductive layer structure where the component carrier further comprises an electrically insulating material layer embedded in the stack; ii) forming at least one depth mapping hole partially through the stack down to the embedded electrically insulating material layer to obtain a depth indicative information; and iii) forming a cavity in the stack by depth routing based on the depth indicative information, so that the bottom of the cavity comprises the electrically insulating material, and iv) forming the at least one depth mapping hole through the electrically insulating material layer down to the metal layer (below).

According to a further aspect of the disclosure, there is described a method of using depth routing (technique) to map a depth in a component carrier layer stack and to form a cavity in said component carrier layer stack based on the mapped depth.

According to a further aspect of the disclosure, there is described a component carrier comprising: i) a stack comprising at least one electrically insulating layer structure and at least one electrically conductive layer structure; ii) a plurality of cavities (recesses) formed in the stack; iii) a ground layer (e.g., the metal layer described above) arranged in the stack (in particular directly) below the plurality of cavities; and iv) an electrically insulating material layer (structure) (as described above) on top of the ground layer (in particular between the ground layer and at least one cavity bottom).

In particular, the component carrier may comprise at least one depth (mapping) hole that extends through the electrically insulating material layer down to the ground layer.

In the context of the present document, the term “depth routing”, also termed “z-axis milling” or “level milling” may in particular refer to a technique of milling into or through a component carrier. Depth routing may comprise a mechanical process performed by a depth routing machine with a (metallic) bit. In contrast to laser drilling, a through or blind hole formed by depth routing may comprise essentially straight vertical sidewalls, i.e. essentially without a tapering. While a drilling process cuts generally only in the vertical direction under pressure, a milling/routing process may as well cut in the horizontal direction without the need of a strong pressure in the vertical direction.

In the context of the present document, the term “(depth) hole” may in particular refers to a blind or through hole that extends in the vertical (along z-axis) of a component carrier.

A depth hole may be used to obtain an information indicative of a depth in a component carrier layer stack, so it may also be used as a “depth mapping hole”, because it is possible to obtain the depth information and thereby provide a map that reflects the depth information over an area of a stack. For example, a depth hole may be drilled/milled down to an embedded metal layer. As soon as a physical contact with the metal layer established, there may be a signal produced (e.g. by closing a short circuit or variation of current/voltage) that is indicative of the specific depth, in this case the depth of the metal layer in the stack. Specifically, the depth hole may be applied to map the depth of a layer (in particular an insulating layer) arranged directly above said metal layer. Forming a depth mapping hole, in particular a plurality of depth mapping holes, may provide the advantage that irregular heights of a layer within the stack can be determined and taken into account, when the actual cavity formation process starts.

In the context of the present document, the term “peripheral recess” may refer to a hole and/or groove formed at the bottom of a component carrier cavity. Hereby, the peripheral recess may be located closer to a peripheral part of the cavity bottom than to a central part of the cavity bottom. Besides the bottom, the cavity may be defined by sidewalls that delimit the cavity. The region close to the sidewalls may be seen as the peripheral region of the cavity bottom. The peripheral recess may thus be located in said peripheral region, either in physical contact with at least one sidewall of the cavity or close (in proximity of, adjacent) to at least one sidewall of the cavity. While the term “hole” may refer to a (circular) recess that extends along the vertical (z) direction, the term “groove” may rather refer to a recess elongated along the horizontal (x, y) direction.

In the context of the present document, the term “component carrier” may particularly denote any support structure which is capable of accommodating one or more components thereon and/or therein for providing mechanical support and/or electrical connectivity. In other words, a component carrier may be configured as a mechanical and/or electronic carrier for components. In particular, a component carrier may be one of a printed circuit board, an organic interposer, a metal core substrate, an inorganic substrate and an IC (integrated circuit) substrate. A component carrier may also be a hybrid board combining different ones of the above-mentioned types of component carriers.

According to an exemplary embodiment, the disclosure may be based on the idea that a cavity in a component carrier layer stack can be formed in an accurate and reliable manner, when a depth mapping hole is formed partially through the layer stack to retrieve a depth indicative information that is in turn used to control a subsequent depth routing process to provide the cavity of a specific size and depth in the stack.

Conventionally, cavities in component carrier stacks are formed for example using laser drilling around a part of the stack that should be removed. After the drilling, the part to be removed is only connected to the rest of the stack by an embedded release layer, so that an easy removal together with the release layer is enabled (so-called cap removal technique). However, this approach comes to its limits with respect to accuracy, when the stack comprises a plurality of layers. The more layers a stack comprises and the thinner these layers are, the more difficult it may be to determine the drilling depth (e.g., down to the release layer). Furthermore, the application of a laser may lead to the formation of tapering sidewalls which may be undesirable in some cases.

It has now been surprisingly found by the inventors that a very accurate cavity formation may be provided by depth routing, which applies a milling instead of a drilling hole formation process. The depth of the routing may be especially reliable because it is hereby guided by a depth indicative information that has been previously determined by the formation of a depth mapping hole. Preferably, the depth mapping hole and the depth routing may be performed both with a depth routing machine, in particular the same depth routing machine. Thereby, the depth indicative information can be directly transferred from one process step to the other.

The accordingly provided cavity may be highly accurate, even though the stack may comprise a plurality of (very thin) layers. Such a stack with cavity may be applied as a cover structure for another component carrier with a surface-mounted component, since the component may be directly accommodated within the high-precision cavity. In this manner, a bulky interposer known from the prior art (see FIG. 4) may become obsolete.

The described manufacture method may be further directly implemented in an easy and cost-efficient manner into existing production lines.

### OVERVIEW OF EMBODIMENTS

According to an embodiment, the peripheral recess comprises a hole extending through the electrically insulating material layer down to the metal layer. In other words, the recess may extend in the vertical direction to the metal layer below the electrically insulating layer.

According to a further embodiment, the hole is configured as a depth mapping hole. This design may be advantageous in case the thickness for the electrically insulating layer structure is too thin to be routed by a depth routing machine efficiently (the machine may route through the thin layer without it being noticed). But when a physical contact with the metal layer below is established, the exact depth can be determined.

According to a further embodiment, the peripheral recess comprises a groove at least partially provided along at least one sidewall of the cavity. This design may be advantageous, when the metal layer comprises one or more protrusions. The electric contact may be established too early, i.e., when the protrusion is met by the routing machine. Yet, in case of a peripheral groove at the same height, correction may be possible.

According to a further embodiment, the groove is adjacent, in particular in physical contact, to at least one sidewall of the cavity. In other words, the peripheral recess comprises a groove at least partially provided along the cavity peripheral wall. In an example, the component carrier may have a high warpage (curvature) at the bottom of the cavity, resulting in a groove provided only on portion(s) on this periphery (due to the movement of the depth routing machine at a constant height).

In a further embodiment, the peripheral recess comprises both, a depth mapping hole and a peripheral groove: here, the depth routing machine provides the hole in the first place and then moves on to a height, where the peripheral groove can be provided.

According to a further embodiment, at least one sidewall (peripheral wall) of the cavity is a (essentially) vertical sidewall. In particular, the sidewall does essentially not taper. These structural features may reflect a manufacturing step of depth routing. Depth routing applies a milling instead of a drilling process. While the latter, in particular in case of laser drilling, forms sidewalls that taper in the drilling direction, the first may lead to essentially straight sidewalls that do not taper. In this respect, the term “essentially” may particularly express that, even so a minor tapering (and/or not fully straight sidewall) may be unavoidable, the tapering is significantly less pronounced than in case of (laser) drilling.

This may provide the advantage that the cavity may be formed in an especially accurate and reliable manner.

According to a further embodiment, the at least one depth mapping hole is located in the cavity. The depth mapping hole may be formed in the same location, where later a depth routing hole/slit/groove will be formed. This may provide the advantage that the depth indicative information may be directly transferred from one process step to the other, since the level of the depth is essentially the same.

According to a further embodiment, the at least one depth mapping hole is located in the stack besides the cavity. In this example, the depth mapping hole is formed in a different location as the depth routing hole/slit/groove, for example next/adjacent to it. In this manner, more information about the depth conditions in the stack may be obtained, e.g., a more detailed depth map can be provided. This may further provide the advantage that the average depth can be obtained, which may further offset the effect of warpage or variation of dielectric layer thickness.

According to a further embodiment, the electrically insulating material layer comprises a central part and a surrounding part (which at least partially surrounds the central part). The surrounding part can be (at least partially) the peripheral recess, in particular when the peripheral recess is configures as a groove. In other words, the bottom of the cavity may comprise an elevated part and a groove-shaped part. Hereby, the groove-shaped part may be located between the elevated part and the cavity sidewall(s). The central part is elevated with respect to the surrounding part, which may reflect a manufacturing step of depth routing. This is because the depth routing forms a groove only in the outer part of the cavity during a cap removal approach. Since the depth routing does not mill the central part, this one is elevated with respect to the surrounding part, which is all-in-all a residue of the milling step. In particular, the surrounding part comprises a groove that at least partially extends along a peripheral wall of the cavity. This structural feature may be the remains of a depth routing step.

According to a further embodiment, the at least one depth mapping hole is formed in the surrounding part. In other words, the depth routing hole/slit is formed at the same location, where previously the depth mapping hole has been drilled (or milled in case that depth routing is used). This may provide the advantage that the depth indicative information may be directly transferred from the depth mapping hole to the actual depth routing process, since the level of the depth to be reached is essentially the same at a similar location.

According to a further embodiment, the component carrier further comprises an electrically conductive material (in particular a conductor track) arranged at the surrounding part. In an embodiment, such an electrically conductive structure may be provided e.g. by plating or PVD/CVD. An electrically conductive material in the cavity may be especially interesting, when the cavity is used to accommodate an electronic component, which may be electrically connected within the cavity.

In another example, the electrically conductive material is additionally or alternatively formed at the central part.

In an example, the electrically conductive material is electrically connected to the metal layer below. Thereby, an efficient and robust electrical connection may be established.

According to a further embodiment, the component carrier further comprises a wiring (e.g., comprising a metal trace, a pad/via, a frame) electrically connected to the metal layer, so that, when a depth routing machine, in particular the metallic mill bit, is brought in physical contact with the metal layer, an electric contact, in particular a short circuit, is established. This may provide the advantage that an efficient alarm system is obtained that immediately indicates when a desired depth is reached. From the location of the metal layer, it may be directly derived at which depth the electrically insulating material layer is arranged. Thus, a valuable depth map may be provided.

In an example, the metal layer is (part of) a ground layer. In particular, the ground layer is arranged below a plurality of cavities in the component carrier, so that the electrically insulating layer structure may be arranged between at least one (in particular all) cavity bottoms and the ground layer. This can provide the advantage that a plurality of cavities (in particular all cavities) are connected to the same ground layer, so that the electric contact (to the drilling machine) can be established for each cavity independently using only one ground layer. In an example, the ground layer and one or more conductive traces are connected between cavities and further connected to cards or frames or pad located in the component carrier (panel).

In an example, the component carrier comprises a metal trace (being part of the wiring) that connects the metal layer or a plurality of metal layers (as one or more ground layers) to a (array) frame and/or to an outer surface of the component carrier (e.g., a side surface or main surface.

In an example, a plurality of metal layers are arranged in a metal layer array. Each metal layer may be termed a ground layer or the whole array may be termed a discontinuous ground layer. The metal array may be electrically connected by a respective metal trace to the (array) frame and/or the outer surface. In an example, the (array) frame is further electrically connected to the outer surface. The electric connection may be realized by a conductive via. At the outer surface, there may be arranged a conductive connection structure, such as a pad, that is further connectable at the outside of the stack/component carrier, e.g., to a depth routing machine. Thereby, an electronic circuit between the ground layer and a depth routing machine bit (through the wiring) can be established. The ground layer connection may hereby be used by a plurality of different cavities independently.

In an example, a plurality of depth mapping holes may be formed, so that a detailed height map can be derived that reflects small height changes within the stack.

In another example, the metal layer may be electrically connected to a ground layer and/or a frame (in case of an array of metal layers, an array frame) of the stack. The ground layer/frame may be connected to a pad (e.g., by a metal trace) or via to the outside of the stack. The pad/via may be further electrically connected to the depth routing machine, so that the machine may automatically slow down or stop, when the electric contact to the metal layer, through the wiring, is established.

According to a further embodiment, the cavity comprises a depth of 1 mm or more, in particular 1.5 mm or more, further in particular 1.8 mm or more. Thus, even though a cavity may be formed through a high number of layer structures, the requirements to accuracy can still be fulfilled.

According to a further embodiment, the electrically insulating material layer comprises a thickness of 100 μm or less, in particular 75 μm or less. Thus, even though a thin layer is used as a base layer for the cap removal, the depth in the stack may still be accurately determined using the described approach. The thickness may be suitable for one-time depth routing. In another example, wherein there is used depth routing in the first place and laser cutting in the second place, a larger thickness may be applied.

According to a further embodiment of the assembly, the electrically conductive material (in particular the conductor track at the surrounding part and/or at the central part) at the bottom of the cavity is electrically connected to the electronic component (sandwiched between the component carriers). Thereby, a reliable electric connection can be established in a straightforward and cost-efficient manner.

According to a further embodiment of the assembly, the further component carrier is configured as a main board, and the component carrier is configured as a radio frequency, RF, board (or vice versa). This may provide the advantage that economically important applications may be directly manufactured with a thin design that may still be highly accurate and reliable.

According to a further embodiment of the assembly, the further component carrier comprises a further recess, and the electronic component is partially accommodated in the cavity and the further cavity, respectively.

According to a further embodiment of the assembly, the component carrier and the further component carrier are connected without an interposer structure in between.

In the context of the present document, the term “interposer” may refer to any (layer) structure that is suitable to be placed between two component carriers in a component carrier assembly. The interposer may thereby serve as a support structure and/or a spacer structure between the component carriers. In particular, an electronic component should be arranged (sandwiched) between the component carriers, whereby the interposer(s) at least partially surround the component to form a pseudo-cavity. The interposer may for example comprise a PCB-material such as resin. A component carrier interconnection such as adhesive paste or solder balls may not be considered as an interposer.

The described interposers lead to a large thickness (in the z-direction) of the assembly and additional material/manufacture costs. In the light of height and cost reduction requirements, it may be considered advantageous to provide a thin assembly without the interposer.

Using the described high accuracy cavity (in the multi-layer stack), the component may be efficiently protected by (and optionally electrically connected within) the cavity (see e.g. FIG. 3B).

According to a further embodiment of the method, forming the at least one depth mapping hole is done by depth routing. This may provide the advantage that the same process may be used for depth determination and depth routing. In this manner, the depth routing may be especially accurate, while process costs may be saved.

According to a further embodiment of the method, the stack further comprises a metal layer below the electrically insulating material layer, and wherein the method further comprises: forming the at least one depth hole through the electrically insulating material layer down to the metal layer (see above).

According to a further embodiment of the method, forming the depth mapping hole comprises establishing an electric contact, in particular a short circuit, when a depth routing machine, in particular the metallic (mill) bit, is brought, after drilling through the electrically insulating material layer, in physical contact with the metal layer. This may provide the advantage that, essentially without taking further measures, an efficient depth determination system is provided.

According to a further embodiment, the method further comprises: taking an action when said electric contact is established, in particular stopping or slowing down the depth routing. Thus, the electric contact may serve as an alarm system that provides a signal when the desired depth is reached. The measured depth of the metal layer in the stack may be used as or within a depth map to accurately determine the depth of the electrically insulating material layer (directly) above the metal layer. In an example, the depth routing machine is electrically connected so that, upon the electric contact, the depth routing will (immediately) stop.

According to a further embodiment, the tolerance of the depth routing is 75 m or less, in particular 45 μm or less, in particular 30 μm or less, more in particular 15 μm or less. In other words, a highly accurate result (with respect to the quality of the cavity) may be achieved using the described approach of depth routing in combination with depth mapping.

According to a further embodiment, the method further comprises: i) providing a release layer in the stack above, in particular directly above, the electrically insulating material layer, and ii) forming further layer structures on top of the release layer.

The described approach may be termed “cap removal” and is based on the idea to build the part of the stack that should be removed on a release layer. A release layer may be any kind of layer suitable to be embedded in a layer stack and to be removable, in particular without leaving residues, together with layers formed above.

According to a further embodiment, the method further comprises removing a portion of the stack, which portion is arranged directly above the release layer, and the release layer from the stack subsequently to the depth routing, so that the cavity is left behind in the stack. In this manner, known and standardized methods may be directly applied to enable a cap removal step after forming the especially accurate depth routing grooves around the part to be removed.

In an embodiment, the component carrier comprises a stack of at least one electrically insulating layer structure and at least one electrically conductive layer structure. For example, the component carrier may be a laminate of the mentioned electrically insulating layer structure(s) and electrically conductive layer structure(s), in particular formed by applying mechanical pressure and/or thermal energy. The mentioned stack may provide a plate-shaped component carrier capable of providing a large mounting surface for further components and being nevertheless very thin and compact. The term “layer structure” may particularly denote a continuous layer, a patterned layer or a plurality of non-consecutive islands within a common plane.

In an embodiment, the component carrier is shaped as a plate. This contributes to the compact design, wherein the component carrier nevertheless provides a large basis for mounting components thereon. Furthermore, in particular a bare die as example for an embedded electronic component, can be conveniently embedded, thanks to its small thickness, into a thin plate such as a printed circuit board.

In an embodiment, the component carrier is configured as one of the group consisting of a printed circuit board, a substrate (in particular an IC substrate), and an interposer.

In the context of the present application, the term “printed circuit board” (PCB) may particularly denote a plate-shaped component carrier which is formed by laminating several electrically conductive layer structures with several electrically insulating layer structures, for instance by applying pressure and/or by the supply of thermal energy. As preferred materials for PCB technology, the electrically conductive layer structures are made of copper, whereas the electrically insulating layer structures may comprise resin and/or glass fibers, so-called prepreg or FR4 material. The various electrically conductive layer structures may be connected to one another in a desired way by forming holes through the laminate, for instance by laser drilling or mechanical drilling, and by partially or fully filling them with electrically conductive material (in particular copper), thereby forming vias or any other through-hole connections. The filled hole either connects the whole stack, (through-hole connections extending through several layers or the entire stack), or the filled hole connects at least two electrically conductive layers, called via. Similarly, optical interconnections can be formed through individual layers of the stack in order to receive an electro-optical circuit board (EOCB). Apart from one or more components which may be embedded in a printed circuit board, a printed circuit board is usually configured for accommodating one or more components on one or both opposing surfaces of the plate-shaped printed circuit board. They may be connected to the respective main surface by soldering. A dielectric part of a PCB may be composed of resin with reinforcing fibers (such as glass fibers).

In the context of the present application, the term “substrate” may particularly denote a small component carrier. A substrate may be a, in relation to a PCB, comparably small component carrier onto which one or more components may be mounted and that may act as a connection medium between one or more chip(s) and a further PCB. For instance, a substrate may have substantially the same size as a component (in particular an electronic component) to be mounted thereon (for instance in case of a Chip Scale Package (CSP)). More specifically, a substrate can be understood as a carrier for electrical connections or electrical networks as well as component carrier comparable to a printed circuit board (PCB), however with a considerably higher density of laterally and/or vertically arranged connections. Lateral connections are for example conductive paths, whereas vertical connections may be for example drill holes. These lateral and/or vertical connections are arranged within the substrate and can be used to provide electrical, thermal and/or mechanical connections of housed components or unhoused components (such as bare dies), particularly of IC chips, with a printed circuit board or intermediate printed circuit board. Thus, the term “substrate” also includes “IC substrates”. A dielectric part of a substrate may be composed of resin with reinforcing particles (such as reinforcing spheres, in particular glass spheres).

The substrate or interposer may comprise or consist of at least a layer of glass, silicon (Si) and/or a photoimageable or dry-etchable organic material like epoxy-based build-up material (such as epoxy-based build-up film) or polymer compounds (which may or may not include photo-and/or thermosensitive molecules) like polyimide or polybenzoxazole.

In an embodiment, the at least one electrically insulating layer structure comprises at least one of the group consisting of a resin or a polymer, such as epoxy resin, cyanate ester resin, benzocyclobutene resin, bismaleimide-triazine resin, polyphenylene derivate (e.g. based on polyphenylenether, PPE), polyimide (PI), polyamide (PA), liquid crystal polymer (LCP), polytetrafluoroethylene (PTFE) and/or a combination thereof. Reinforcing structures such as webs, fibers, spheres or other kinds of filler particles, for example made of glass (multilayer glass) in order to form a composite, could be used as well. A semi-cured resin in combination with a reinforcing agent, e.g. fibers impregnated with the above-mentioned resins is called prepreg. These prepregs are often named after their properties e.g. FR4 or FR5, which describe their flame-retardant properties. Although prepreg particularly FR4 are usually preferred for rigid PCBs, other materials, in particular epoxy-based build-up materials (such as build-up films) or photoimageable dielectric materials, may be used as well. For high frequency applications, high-frequency materials such as polytetrafluoroethylene, liquid crystal polymer and/or cyanate ester resins, may be preferred. Besides these polymers, low temperature cofired ceramics (LTCC) or other low, very low or ultra-low DK materials may be applied in the component carrier as electrically insulating structures.

In an embodiment, the at least one electrically conductive layer structure comprises at least one of the group consisting of copper, aluminum, nickel, silver, gold, palladium, tungsten and magnesium. Although copper is usually preferred, other materials or coated versions thereof are possible as well, in particular materials coated with supra-conductive material or conductive polymers, such as graphene or poly(3,4-ethylenedioxythiophene) (PEDOT), respectively.

At least one component may be embedded in the component carrier and/or may be surface mounted on the component carrier. Such a component can be selected from a group consisting of an electrically non-conductive inlay, an electrically conductive inlay (such as a metal inlay, preferably comprising copper or aluminum), a heat transfer unit (for example a heat pipe), a light guiding element (for example an optical waveguide or a light conductor connection), an electronic component, or combinations thereof. An inlay can be for instance a metal block, with or without an insulating material coating (IMS-inlay), which could be either embedded or surface mounted for the purpose of facilitating heat dissipation. Suitable materials are defined according to their thermal conductivity, which should be at least 2 W/mK. Such materials are often based, but not limited to metals, metal-oxides and/or ceramics as for instance copper, aluminum oxide (Al₂O₃) or aluminum nitride (AlN). In order to increase the heat exchange capacity, other geometries with increased surface area are frequently used as well. Furthermore, a component can be an active electronic component (having at least one p-n-junction implemented), a passive electronic component such as a resistor, an inductance, or capacitor, an electronic chip, a storage device (for instance a DRAM or another data memory), a filter, an integrated circuit (such as field-programmable gate array (FPGA), programmable array logic (PAL), generic array logic (GAL) and complex programmable logic devices (CPLDs)), a signal processing component, a power management component (such as a field-effect transistor (FET), metal-oxide-semiconductor field-effect transistor (MOSFET), complementary metal-oxide-semiconductor (CMOS), junction field-effect transistor (JFET), or insulated-gate field-effect transistor (IGFET), all based on semiconductor materials such as silicon carbide (SiC), gallium arsenide (GaAs), gallium nitride (GaN), gallium oxide (Ga₂O₃), indium gallium arsenide (InGaAs) and/or any other suitable inorganic compound), an optoelectronic interface element, a light emitting diode, a photocoupler, a voltage converter (for example a DC/DC converter or an AC/DC converter), a cryptographic component, a transmitter and/or receiver, an electromechanical transducer, a sensor, an actuator, a microelectromechanical system (MEMS), a microprocessor, a capacitor, a resistor, an inductance, a battery, a switch, a camera, an antenna, a logic chip, and an energy harvesting unit. However, other components may be embedded in the component carrier. For example, a magnetic element can be used as a component. Such a magnetic element may be a permanent magnetic element (such as a ferromagnetic element, an antiferromagnetic element, a multiferroic element or a ferrimagnetic element, for instance a ferrite core) or may be a paramagnetic element. However, the component may also be an IC substrate, an interposer or a further component carrier, for example in a board-in-board configuration. The component may be surface mounted on the component carrier and/or may be embedded in an interior thereof. Moreover, other components, in particular those which generate and emit electromagnetic radiation and/or are sensitive with regard to electromagnetic radiation propagating from an environment, may be used as a component.

In an embodiment, the component carrier is a laminate-type component carrier. In such an embodiment, the component carrier is a compound of multiple layer structures which are stacked and connected together by applying a pressing force and/or heat.

After processing interior layer structures of the component carrier, it is possible to cover (in particular by lamination) one or both opposing main surfaces of the processed layer structures symmetrically or asymmetrically with one or more further electrically insulating layer structures and/or electrically conductive layer structures. In other words, a build-up may be continued until a desired number of layers is obtained.

After having completed formation of a stack of electrically

insulating layer structures and electrically conductive layer structures, it is possible to proceed with a surface treatment of the obtained layers structures or component carrier.

In particular, an electrically insulating solder resist may be applied to one or both opposing main surfaces of the layer stack or component carrier in terms of surface treatment. For instance, it is possible to form such a solder resist on an entire main surface and to subsequently pattern the layer of solder resist so as to expose one or more electrically conductive surface portions which shall be used for electrically coupling the component carrier to an electronic periphery. The surface portions of the component carrier remaining covered with solder resist may be efficiently protected against oxidation or corrosion, in particular surface portions containing copper.

It is also possible to apply a surface finish selectively to exposed electrically conductive surface portions of the component carrier in terms of surface treatment. Such a surface finish may be an electrically conductive cover material on exposed electrically conductive layer structures (such as pads, conductive tracks, etc., in particular comprising or consisting of copper) on a surface of a component carrier. If such exposed electrically conductive layer structures are left unprotected, then the exposed electrically conductive component carrier material (in particular copper) might oxidize, making the component carrier less reliable.

A surface finish may then be formed for instance as an interface between a surface mounted component and the component carrier. The surface finish has the function to protect the exposed electrically conductive layer structures (in particular copper circuitry) and enable a joining process with one or more components, for instance by soldering. Examples for appropriate materials for a surface finish are Organic Solderability Preservative (OSP), Electroless Nickel Immersion Gold (ENIG), Electroless Nickel Immersion Palladium Immersion Gold (ENIPIG), gold (in particular hard gold), chemical tin, nickel-gold, nickel-palladium, etc.

### BRIEF DESCRIPTION OF THE DRAWINGS

The aspects defined above and further aspects of the disclosure are apparent from the examples of embodiment to be described hereinafter and are explained with reference to these examples of embodiment.

FIG. 1 shows a side view of a component carrier according to an exemplary embodiment of the disclosure.

FIG. 2 shows a detailed view of the cavity according to an exemplary embodiment of the disclosure.

FIG. 3A and FIG. 3B show a component carrier assembly according to an exemplary embodiment of the disclosure.

FIG. 4 shows an assembly from the prior art.

FIG. 5 shows a method of forming a depth mapping hole by a depth routing machine according to an exemplary embodiment of the disclosure.

FIG. 6 shows a top view on a cross-section of the layer stack according to an exemplary embodiment of the disclosure.

FIG. 7A, FIG. 7B, FIG. 7C, FIG. 7D, FIG. 7E, and FIG. 7F show a method of manufacturing a component carrier according to an exemplary embodiment of the disclosure.

FIG. 8, FIG. 9, FIG. 10, FIG. 11, and FIG. 12 show a wiring of the metal layer according to exemplary embodiments of the disclosure.

### DETAILED DESCRIPTION OF THE ILLUSTRATED EMBODIMENTS

The illustrations in the drawings are schematically presented. In different drawings, similar or identical elements are provided with the same reference signs.

Before, referring to the drawings, exemplary embodiments will be described in further detail, some basic considerations will be summarized based on which exemplary embodiments of the disclosure have been developed.

According to an exemplary embodiment, there is provided a reliable cap removal method for HVM (high volume manufacturing) production with a thick cavity recess to meet Z-height requirements for assembled PCBs. There are cost savings on thick cavity formation compared to laser cutting cap removal.

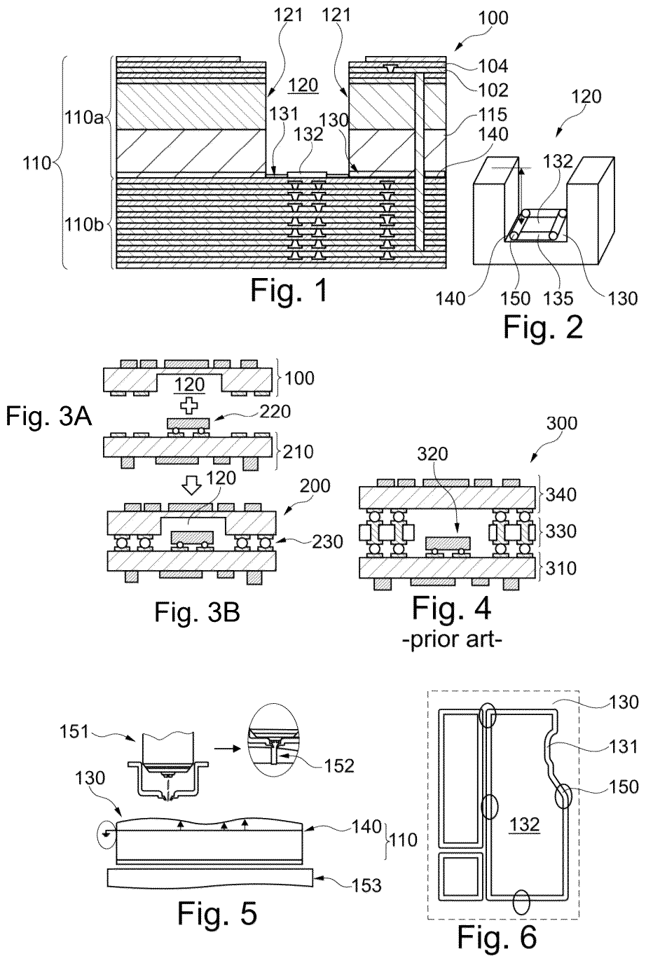

FIG. 1 shows a side view of a component carrier 100 according to an exemplary embodiment of the disclosure. The component carrier 100 comprises a stack 110 with a plurality of electrically insulating layer structures 102 and electrically conductive layer structures 104. The component carrier 100 can be divided in an upper part 110a (cavity-surrounding stack) and a lower part 110b (base stack) with respect to a cavity 120. The upper part 110a can comprises a core layer structure 115, for example fully cured dielectric material such as FR4. There is arranged a plurality of alternating electrically insulating layer structures 102 and electrically conductive layer structures 104 in the stack 110. In the upper part (110a (in this example below the core layer structure 115), there is arranged an electrically insulating material layer structure 130, for example a prepreg.

The cavity 120 is formed in the upper part 110a of the stack 110, through the plurality of layer structures 102, 104. Hereby, the electrically insulating material layer 130 forms the bottom of said cavity 120. The electrically insulating material layer 130 comprises a central part 132 (elevated) and a peripheral recess (surrounding part) 131 that forms a groove between the central part 132 and the sidewalls 121 of the cavity 120.

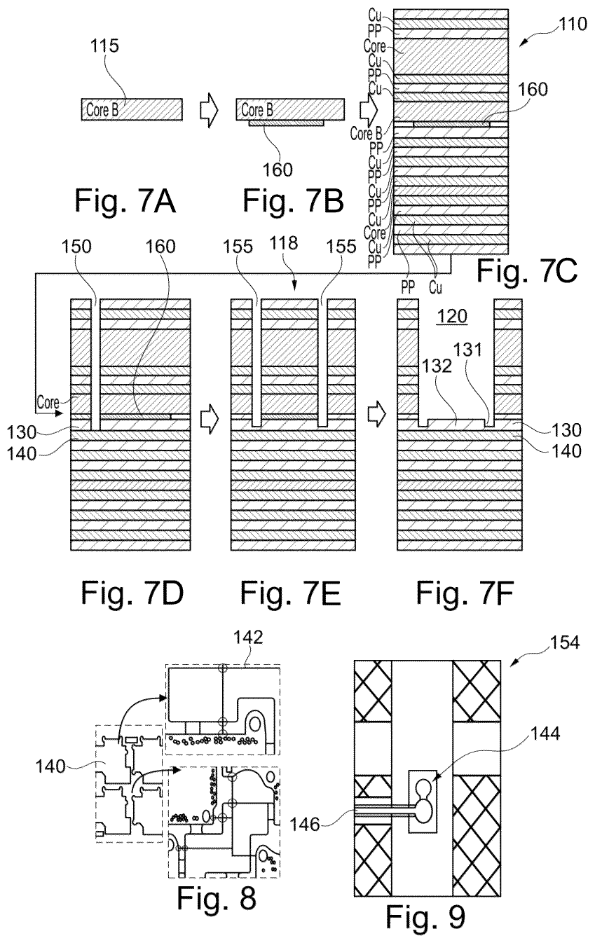

Directly below the cavity 120, there is arranged the lower component carrier part 110b which comprises a further plurality of electrically insulating layer structures 102 and electrically conductive layer structures 104 (but, in this example, no core layer). A metal layer 140 (e.g., plated on a resin layer) is arranged in the stack 110 directly below the electrically insulating material layer 130 and forms the uppermost layer of the lower component carrier part 110b. At the surrounding part 131, there is a small layer of the electrically insulating material layer 130 left that covers the metal layer 140. The surrounding part 131 is a structural feature that reflects the manufacturing method of forming a hole into the stack 110 by depth routing. The milling/routing extends partially into the electrically insulating material layer 130, thereby forming the surrounding part 131. The central part 132, instead, is elevated because it is not affected by the depth routing (see also FIG. 7 below). At least one depth mapping hole 150 extends through the electrically insulating material layer 130 down to the metal layer 140 below (not shown in this Figure, see instead FIG. 2 below).

In other words, the bottom of the cavity 120 has a bottom surface encircled by the cavity peripheral walls 121, wherein a peripheral recess 131 is provided on said bottom of the cavity 120. The peripheral recess 131 comprises a hole 150 extending through the electrically insulating material layer 130 up to the metal layer 140 (said hole 150 is configured as a depth mapping hole). The peripheral recess 131 comprises a groove that is at least partially provided along the cavity peripheral wall 121 and is adjacent (in contact) to the cavity peripheral walls 121.

FIG. 2 shows a detailed side view of the cavity 120 in the component carrier 100 according to an exemplary embodiment of the disclosure. In this view, four depth mapping holes 150 extend through the electrically insulating material layer 130 down to the metal layer 140 below, thereby partially exposing the metal layer 140 surface. An electrically conductive material 135, here a conductor track, is arranged at the surrounding part 131 (in the groove). The electrically conductive material 135 can be additionally arranged in the cavity 120, e.g., by plating. The electrically conductive material 135 can be further electrically connected to the metal layer 140 below.

FIGS. 3A and 3B show a component carrier assembly 200 according to an exemplary embodiment of the disclosure.

As shown in FIG. 3A the component carrier 100 as described above (e.g., configured as a radio frequency board here), with the cavity 120, is used as a cover structure. A further component carrier 210 (e.g., configured as a mainboard), which does not comprise a cavity but a surface-mounted electronic component 220 (e.g., an IC), is used as a base structure.

As shown in FIG. 3B the component carrier 100 is arranged on the further component carrier 210, so that the electronic component 220 is located at least partially in the cavity 120. In this example, the connection is established by solder balls 230. The above described electrically conductive material 135 at the bottom of the cavity 120 can now be used to establish an electrical connection with the surface-mounted electronic component 220. In contrast to the prior art example shown in FIG. 4, the component carrier and the further component carrier are connected without an interposer structure in between.

FIG. 5 shows the formation of a depth routing (mapping) hole by a depth routing machine according to an exemplary embodiment of the disclosure. Below the electrically insulating material layer 130, there is arranged the metal layer 140. The stack 110 to be processed is placed on a machine table 153. The depth routing machine 151 comprises a metallic bit 152 that mills through the stack 110 and through the electrically insulating material layer 130. Once the metallic bit 152 gets in physical contact with the metal layer 140, an electric contact, such as a short circuit, is formed. This is because the component carrier 100 comprises a wiring 154 that is electrically connected to the metal layer 140, to thereby form the electric contact and provide a signal to the outside of the stack 110 (e.g., by a via or pad), that the metal layer 140 has been reached by drilling. Said signal may trigger a slow-down or a stop of the depth routing process and may also trigger a record of the depth/height of routing.

FIG. 6 shows a top view on a cross-section through the layer stack 110, in particular on the electrically insulating material layer 130, according to an exemplary embodiment of the disclosure. The electrically insulating material layer 130 comprises several sections of different shape, wherein each section comprises a respective central part 132 that is surrounded by a surrounding part 131 in form of a groove between the central part 132 and the cavity sidewalls 121. For the exemplary section on the right side, four depth mapping holes 150 have been formed to map the depth for the depth routing at different locations. The surrounding part 131 is a structural feature that remains in the electrically insulating material layer 130 after the depth routing step.

FIGS. 7A to 7F show a method of manufacturing a component carrier 100 (as described above) according to an exemplary embodiment of the disclosure.

In FIG. 7A a core layer structure 115 is provided.

In FIG. 7B a release layer 160 is attached to the core layer structure 115.

As shown in FIG. 7C directly below the release layer 160, an electrically insulating material layer 130 (prepreg) is arranged/laminated. Further, a plurality of electrically insulating layer structures 102 and electrically conductive layer structures 104 are build-up above the core layer structure 115 and below the electrically insulating material layer 130, respectively, thereby forming the upper component carrier part 110a and the lower component carrier part 110b. The release layer 160 is now embedded in the stack 110.

In FIG. 7D at least one depth mapping hole 150 is formed through the stack (upper part 110a) and the electrically insulating material layer 130 down to the metal layer 140 by depth routing. As described above, a physical contact between the depth routing machine 151 and the metal layer 140 triggers an electric signal, so that a depth indicative information can be obtained. Based on the depth indicative information, the depth routing is stopped or slowed down.

In FIG. 7E based on the depth indicative information, depth routing (e.g., with a larger bit) is performed down to the electrically insulating material layer 130 (and not into the metal layer 140). In this Figure, the depth mapping hole 150 is not shown for clarity. The depth routing forms a slit 155 in the stack 110 that encircles the portion to be removed 118. By forming the slit 155, the surrounding part 131 in the electrically insulating material layer 130 is produced as a structural feature. Hereby, the stack 110 is separated from the portion 118 to be removed, which portion 118 is arranged directly above the release layer 160.

In FIG. 7F the release layer 160 and the portion to be removed 118 (with the further layer structures 102, 104 on top of the release layer 160) above are removed from the stack 110 subsequently to the depth routing, thereby leaving behind the cavity 120 in the stack 110. The electrically insulating material layer 130 forms the bottom of the cavity 120 with the central part 132 and the surrounding part 131.

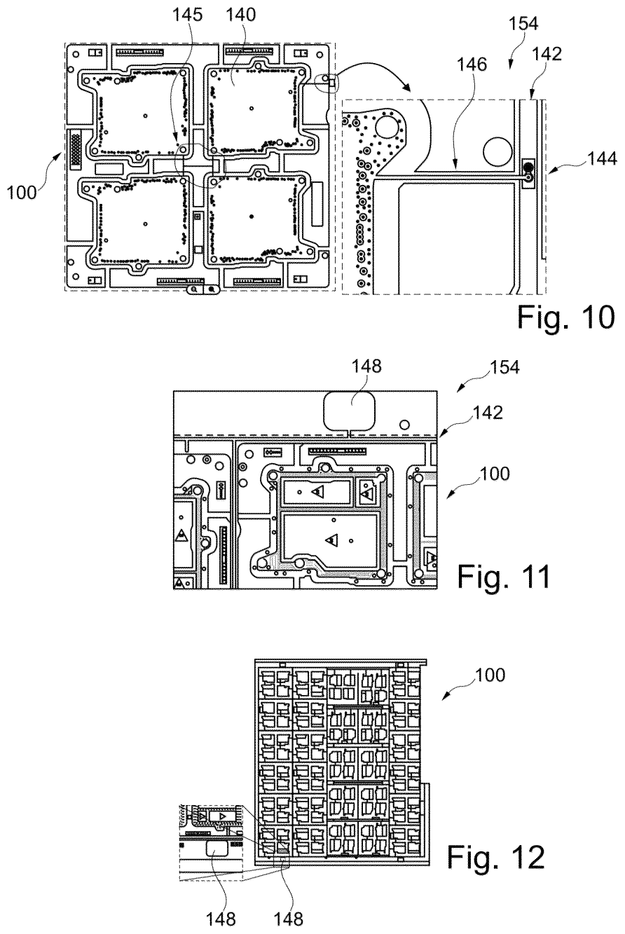

FIGS. 8 to 12 show a wiring 154 of the metal layer 140 according to exemplary embodiments of the disclosure.

FIGS. 8 and 9 show a top view on a cross section along the x-y plane (horizontal) that shows several metal layers 140 as a ground layer in detailed view. A metal trace 146 connects the metal layers 140 respectively to a (array) frame 142 and further, by a via 144, to an outer surface. FIG. 8 shows on the left side a top view on the metal layer(s) 140 and besides two enlarged detailed top views.

FIG. 10 shows that each metal layer 140 in a metal layer array is electrically connected by a respective metal trace 146 to the array frame 142. As can be seen in the detailed view on the right, the array frame 142 is further electrically connected to the outset layer by a via (mechanically or laser drilled) 144. These vias of the array frame 142 can be further interconnected at an outside of the stack/component carrier.

FIG. 11 shows an example, where the array frame 142 is electrically connected to a pad 148 that is further connectable to the outside of the stack/component carrier, e.g., to a depth routing machine. Thereby, an electronic circuit between metal layer 140 and depth routing machine bit through the wiring 154 can be established.

FIG. 12 shows an example of a top view on the whole component carrier 100, whereby only four pads 148 are used for a plurality of (interconnected) depth mapping holes 150.

### REFERENCE SIGNS

100 Component carrier
102 Electrically insulating layer structure
104 Electrically conductive layer structure
110 Stack
110a Upper part, cavity surrounding stack
110b Lower part, base stack
115 Core layer structure
118 Portion of the stack to be removed
120 Cavity
121 Cavity sidewall
130 Electrically insulating material layer, prepreg
131 Peripheral recess, surrounding part
132 Central part
135 Electrically conductive material, conductor track
140 Metal layer
142 Array frame
144 Via (to outer layer surface)
145 Ground layer connection
146 Metal trace, ground layer
148 Pad
150 Depth (routing) mapping hole
151 Depth routing machine
152 Metallic bit
153 Machine table
154 Wiring
155 Depth routing hole/slit
160 Release layer
200 Component carrier assembly
210 Further component carrier
220 Electronic component
230 Interconnection
300 Prior art assembly
310 Prior art first circuit board
320 Prior art IC
330 Prior art interposer
340 Prior art second circuit board

1. A component carrier, comprising:
a stack comprising at least one electrically insulating layer structure and at least one electrically conductive layer structure;
a cavity formed in the stack;
an electrically insulating material layer arranged in the stack, at least partially defining the bottom of the cavity; and
a metal layer arranged in the stack below the electrically insulating material layer;
wherein the bottom of the cavity comprises a bottom surface encircled by the sidewalls of the cavity, and
wherein a peripheral recess is formed on the bottom of the cavity.

2. The component carrier according to claim 1,
wherein the peripheral recess comprises a hole extending through the electrically insulating material layer down to the metal layer.

3. The component carrier according to claim 2,
wherein the hole is configured as a depth mapping hole.

4. The component carrier according to claim 1,
wherein the peripheral recess comprises a groove at least partially provided along at least one sidewall of the cavity.

5. The component carrier according to claim 4,
wherein the groove is adjacent to at least one sidewall of the cavity.

6. The component carrier according to claim 1,
wherein at least one sidewall of the cavity is an essentially straight sidewall which reflects a manufacturing step of depth routing, wherein the sidewall does essentially not taper.

7. The component carrier according to claim 1,
wherein the peripheral recess reflects a manufacturing step of depth routing.

8. The component carrier according to claim 1, further comprising:
an electrically conductive material arranged at the peripheral recess, wherein the electrically conductive material is electrically connected to the metal layer below.

9. The component carrier according to claim 1, further comprising:
a wiring electrically connected to the metal layer, so that, when a depth routing machine is brought in physical contact with the metal layer, an electric contact is established.

10. The component carrier according to claim 1,
wherein the cavity comprises a depth of 1 mm or more, and/or
wherein the electrically insulating material layer comprises a thickness of 100 μm or less.

11. A component carrier assembly, comprising:
a first component carrier as a base structure;
an electronic component mounted on the first component carrier; and
a second component carrier having a cavity arranged as a cover structure,
wherein the second component carrier is arranged on the first component carrier, so that the electronic component is located at least partially in the cavity.

12. The component carrier assembly according to claim 11,
wherein electrically conductive material at the bottom of the cavity is electrically connected to the electronic component.

13. The component carrier assembly according to claim 11,
wherein the first component carrier is configured as a main board, and
wherein the second component carrier is configured as a radio frequency board.

14. The component carrier assembly according to claim 11,
wherein the second component carrier and the first component carrier are connected without an interposer structure in between.

15. A method of manufacturing a component carrier, the method comprising:
providing a stack comprising at least one electrically insulating layer structure and at least one electrically conductive layer structure, and further comprising an electrically insulating material layer embedded in the stack;
forming at least one depth mapping hole partially through the stack down to the embedded electrically insulating material layer to obtain a depth indicative information; and
forming a cavity in the stack by depth routing based on the depth indicative information, so that the bottom of the cavity comprises the electrically insulating material layer.

16. The method according to claim 15,
wherein forming the at least one depth mapping hole comprises depth routing.

17. The method according to claim 15,
wherein the stack further comprises a metal layer arranged below the electrically insulating material layer, and wherein the method further comprises at least one of the following features:
forming the at least one depth hole through the electrically insulating material layer down to the metal layer;
after milling through the electrically insulating material layer, establishing an electrical contact when a depth routing machine is brought in physical contact with the metal layer; and
taking an action when the electrical contact is established.

18. (canceled)

19. The method according to claim 16,
wherein the tolerance of the depth routing is 75 μm or less.

20. The method according to claim 16, further comprising:
providing a release layer in the stack above the electrically insulating material layer,
forming further layer structures on top of the release layer; and
removing a portion of the stack, which portion is arranged directly above the release layer, and the release layer from the stack subsequently to the depth routing, so that the cavity is left behind in the stack.

21. (canceled)

22. A method, comprising:
mapping a depth in a component carrier layer stack; and
forming a cavity in said component carrier layer stack based on the mapped depth.
